(19) United States
(12) Patent Application Publication
(10) Pub. No.: US 2015/0321162 A1
(43) Pub. Date: Nov. 12, 2015

(54) METAL-NANOPARTICLE-ARRAYS AND PRODUCTION OF METAL-NANOPARTICLE-ARRAYS

(71) Applicant: LEIBNIZ-INSTITUT FÜR NEUE MATERIALIEN GEMEINNÜTZI- GE GESELLSCHAFT MIT BESCHRÄNKTER HAFTUNG, Saarbrücken (DE)

(72) Inventors: Daniel BRODOCEANU, Saarbruecken (DE); Tobias KRAUS, Saarbruecken (DE); Cheng FANG, Bellevue Heights (AU); Nicolas Hans VOELCKER, Blackwood (AU)

(73) Assignees: LEIBNIZ-INSTITUT FUER NEUE MATERIALIEN GEMEINNUETZIGE GESELLSCHAFT MIT; BESCHRAENKTER HAFTUNG, Saarbrücken (DE)

(21) Appl. No.: 14/650,597

(22) PCT Filed: Dec. 12, 2013
(86) PCT No.: PCT/DE2013/100420

§ 371 Date: Jun. 9, 2015

(30) Foreign Application Priority Data
Dec. 14, 2012 (DE) 10 2012 112 299.7

(51) Int. Cl. B01J 19/00; C23C 26/00; C23C 14/16; C23C 16/06; C23C 14/34; C23C 14/30

(52) U.S. Cl. CPC B01J 19/0046; C23C 14/34; C23C 14/30; C23C 14/16; C23C 16/06; C23C 26/00; B01J 2219/00648; B01J 2219/0075; B01J 2219/00443; B01J 2219/00459

(57) ABSTRACT

In metal-nanoparticle arrays and methods of producing metal-nanoparticle arrays, the metal-nanoparticle size and the interparticle distance between the metal nanoparticles can be adjusted. In the method of producing metal-nanoparticle arrays, a colloidal dispersion of microspheres is deposited on a substrate as a densely packed monolayer via convective assembly, after which the deposited monolayer is coated with at least one thinly deposited metal-nanoparticle layer by a physical deposition process, and after which the microspheres deposited on the substrate as a monolayer and coated with at least one metal-nanoparticle layer are removed by thermal decomposition.

Nanoparticle arrays (NP arrays) are typically produced by means of photolithography, electron beam lithography, nanoimprint or colloidal lithography.

A nanoparticle array is here a regular array, e.g. in the form of a grid.

Both in photolithography and in electron beam lithography (E-lithography), use is made of coatings which are exposed via a mask either to UV photons or to an electron beam in order to define a desired pattern. Following the lithographic process, subsequent treatments (such as metal deposition, coating removal, annealing, etc.) produce the final NP array.

Conventional colloidal lithography is based on metal, which is applied between the spheres of a self-assembled monolayer. Patterns of this kind may be annealed in such a way as to convert almost triangular islands into rounded metal nanoparticles.

Another production method for NP arrays involves the use of core-shell (CS) particles, as they are termed. These have a core of metal NP, and the core, in turn, is surrounded by a polymeric shell.

Core-shell (CS) particles may be deposited as densely packed monolayers on almost any smooth surface by way of convective assembly. Following deposition, their shells are thermally decomposed or plasma-etched, leaving the metal-nanoparticle cores in a mostly regular, hexagonal array.

The production methods referred to above have various disadvantages. Photolithography, for example, is a multi-stage and expensive procedure for which additional equipment is required and in which a significant proportion of the metal used is lost. E-lithography is an even more expensive production method. A further drawback here is that the throughput is relatively limited. Colloidal lithography (a less expensive production method), by contrast, usually generates nanoparticle arrays in which the nanoparticles are smaller than the masking particles and therefore only make up a small proportion of the surface.

In production methods using core-shell (CS) particles, the maximum diameter of the particles that decompose into CS compact nanoparticles is currently given as 260 nm (Vogel et. al, Beilstein J. Nanotechnol. 2011, 2, 459). This form of production also limits the maximum possible distance between the nanoparticles.

Furthermore, monodisperse core-shell (CS) particles require a regular array with minimal deviations from the spherical shape. This last condition, however, is difficult to fulfil with the currently used CS-particle syntheses.

The aim of the invention is therefore to develop metal-nanoparticle arrays and a method of producing metal-nanoparticle arrays, with which it is possible to adjust the metal-nanoparticle size and the interparticle distance between the metal nanoparticles.

The aim of providing a method for producing metal-nanoparticle arrays is established according to the invention in that:

a colloidal dispersion of microspheres is deposited on a substrate as a densely packed monolayer via convective assembly,
after which the deposited monolayer is coated with at least one thinly deposited metal-nanoparticle layer by means of a physical deposition process, and
   after which the microspheres deposited on the substrate as a monolayer and coated with at least one metal-nanoparticle layer are removed by thermal decomposition.

Alternatively, the aim of providing a method for producing metal-nanoparticle arrays is achieved according to the invention in that:
microspheres are coated with at least one thinly deposited metal-nanoparticle layer by means of a physical deposition process,
after which the microspheres coated with at least one metal-nanoparticle layer are dispersed colloidally,
after which the colloidal dispersion of microspheres coated with a metal-nanoparticle layer is deposited on a substrate as a densely packed monolayer by convective assembly, and
after which the microspheres coated with at least one metal-nanoparticle layer and deposited on the substrate as a monolayer are removed by thermal decomposition.

The invention advantageously provides for the use of monodisperse polymeric particles or micro-sized polystyrene beads as microspheres, these being commercially available and therefore not involving any additional production costs.

The aim of developing metal-nanoparticle arrays consisting of metal nanoparticles applied on a substrate is likewise achieved in that metal nanoparticles are applied indirectly to the substrate via physical deposition onto a monolayer of densely packed microspheres, the metal nanoparticles bonding to the substrate as a result of thermal decomposition of the monolayer of densely packed microspheres, to the effect that
the microspheres are removed,
the at least one metal-nanoparticle layer is sintered with the substrate,
the metal nanoparticles have a diameter of between 100 nm and 1 μm and
an interparticle distance of between 50 nm and 1.5 μm.

The term “indirect” means here that although the metal nanoparticles are deposited onto the densely packed microsphere monolayer, the microsphere monolayer is removed by thermal decomposition, as a result of which the metal nanoparticles are sintered on the substrate.

The invention provides that, for the metal-nanoparticle arrays, the metal-nanoparticle layer has a thickness of between 10 nm and 1 μm.

The thickness determines the mechanical stability and therefore the adhesive capability of the metal nanoparticles in further processing stages, and influences their optical properties and catalytic activity.

The metal-nanoparticle layer thicknesses are between 10 nm and 1 μm, preferably between 10 nm and 200 nm and, especially preferable, between 40 nm and 100 nm. The metal-nanoparticle layer thickness is preferably between 200 nm and 1 μm.

In a further embodiment of the metal-nanoparticle arrays according to the invention, the metal nanoparticles have a diameter of at least 260 nm.

However, it is also possible for the metal nanoparticles to have a diameter of at least 300 nm. The invention also provides for the metal nanoparticles to have a diameter of at least 320 nm.

Largish particles permit production, via ionic etching or metal-assisted chemical etching, of correspondingly large holes or wires of the kind needed for antireflective coatings or biomimetic adhesion surfaces.

The diameter of the metal nanoparticles may be between 100 nm and 1 μm, and be selected such that they efficiently scatter or efficiently absorb visible or infrared light.

As a preferred embodiment of the metal-nanoparticle arrays, the invention also provides for the metal nanoparticles to have an interparticle distance of between 50 nm and 1.5 μm.

Reflection can be minimized and the transmission of light into the substrate optimized by metal nanoparticles with diameters of between 100 nm and 1 μm, whose interparticle distances are selected to be between 50 nm and 1.5 μm.

Particles with small distances are known to be useful for catalysis, optics and other areas, such as increasing the adhesion of biological cells and the targeted application of pharmacologically active substances.

Flexibly adjustable distances are important, by way of example, for the texturing of oxidic substrates, such as magnesium oxide (MgO) or strontium titanate (SrTiO₃), and for the preparation of pinning centres for type-II superconducting thin films of yttrium barium copper oxide (YBCO).

It is also within the scope of the invention to select interparticle distances of between 500 nm and 1.5 μm.

Interparticle distances greater than 1 μm are also advantageous for the production of semiconductor wires with high aspect ratios via vapour liquid solid growth and for reactive ionic etching or metal-assisted chemical etching.

Wires of this kind can be used as electron emitters, for electrical bonding, for novel types of field effect transistors and for other applications.

In analytical applications (SERs etc.), the particles are advantageously spaced apart so that optical coupling between them is low and the optical responses of the individual particles are read out separately.

Particles with distances below the diffraction limit are difficult to resolve with conventional optics. By contrast, particles arranged to have interparticle distances above the diffraction limit can be read out individually by conventional optical methods.

A further advantage of the metal-nanoparticle arrays is that the metal nanoparticles are arranged in hexagonal arrays.

This is beneficial because a hexagonal array uses the surface efficiently and the position of the neighbouring particle is always known.

However, it is also conceivable for the metal nanoparticles to have a trigonal or quadratic array.

It is to advantage both for the method of producing metal-nanoparticle arrays and for the metal-nanoparticle arrays themselves that the microspheres have a diameter of between 90 nm and 1.2 μm.

Depending on the application, provision is also made for the use of microspheres with a diameter of between 90 nm and 1200 nm, preferably between 200 nm and 1000 nm or between 1000 nm and 1200 nm.

According to another advantageous embodiment of the method of producing metal-nanoparticle arrays and of the metal-nanoparticle arrays themselves, the substrate consists of silicon, glass, quartz glass, a monocrystal, sapphire, polyimide, polytetrafluoroethylene (PTFE) or other oxidic materials, ceramics or metal.

Further examples of oxidic materials include magnesium oxide (MgO) and strontium titanate (SrTiO₃).

Another advantage of the method for producing metal-nanoparticle arrays and of the metal-nanoparticle arrays themselves is that the substrate has a 2-D surface or a 3-D surface.

This means the substrate may be a flat, two-dimensional object, for example, but also a domed surface or a surface of a three-dimensional body.

This embodiment of the invention thus enables the production of both flat and conventional (2-D) nanoparticle arrays and also of curved or domed (3-D) nanoparticle arrays. Domed nanoparticle arrays are useful, for example, for optical fibres, catalytic converters, implantable electrodes and optical lenses. They may be applied onto existing structures in order to effect self-cleaning, delay icing, alter optical transmission and reflection properties or generate a relief hologram by virtue of the regular array.

It is to advantage that the physical deposition method is sputtering, electron beam evaporation, thermal evaporation or pulsed laser deposition.

The invention also makes provision, both for the method of producing metal-nanoparticle arrays and for the metal-nanoparticle arrays themselves, for the metal of the metal-nanoparticle layer or of the metal nanoparticles to be a precious metal.

In this context, it is particularly advantageous that the precious metal is gold (Au), silver (Ag) or platinum (Pt).

The metals Au and Pt can be sintered in air without additional precautions and do not oxidize. All three metals have strong surface plasmons, which make it easy to characterise the array. In addition, the metals are catalytically active.

To facilitate handling, the invention advantageously provides for thermal decomposition to be conducted in a furnace or by using an ethanol flame.

Of course, any other suitable method effecting thermal decomposition of the microspheres may be used as well.

A particular advantage of the method of producing metal-nanoparticle arrays is that, according to the invention, between 90 and 100% of the metal nanoparticles used initially are actually incorporated in the metal nanoparticle array.

The production method makes it possible to apply almost 100% of the metal used onto the array, leading to lower production costs compared to conventional methods.

Undesirable metal-nanoparticle substructures may form during the production of metal-nanoparticle arrays.

For the method of producing metal-nanoparticle arrays, therefore, the invention provides that metal-nanoparticle substructures formed during production be removed following thermal decomposition by means of wet-chemical etching, aqueous I₂/KI being used as etching solution.

For the method of producing metal-nanoparticle arrays, the invention also provides that the metal nanoparticles be sintered with the substrate at a temperature of between 350° C. and 400° C. or between 500° C. and 700° C.

The metal-nanoparticle arrays according to the invention are suitable, for example, as
catalysts for the vapour-liquid-solid (VLS) growth of semiconductor nanowires,
catalysts for metal-assisted etching,
catalysts for currentless electrolytic coating,
catalysts for the decomposition of volatile organic compounds (VOC),
catalysts for self-cleaning surfaces,
optical filters,
three-dimensional biofunctionalisation of surfaces,
decorative coatings
substrates for “Surface Enhanced Raman Spectroscopy (SERS)”
infrared absorbers and reflectors,
surfaces for surface-plasmon analysis.

The invention is explained in detail below by reference to embodiments.

The drawing in

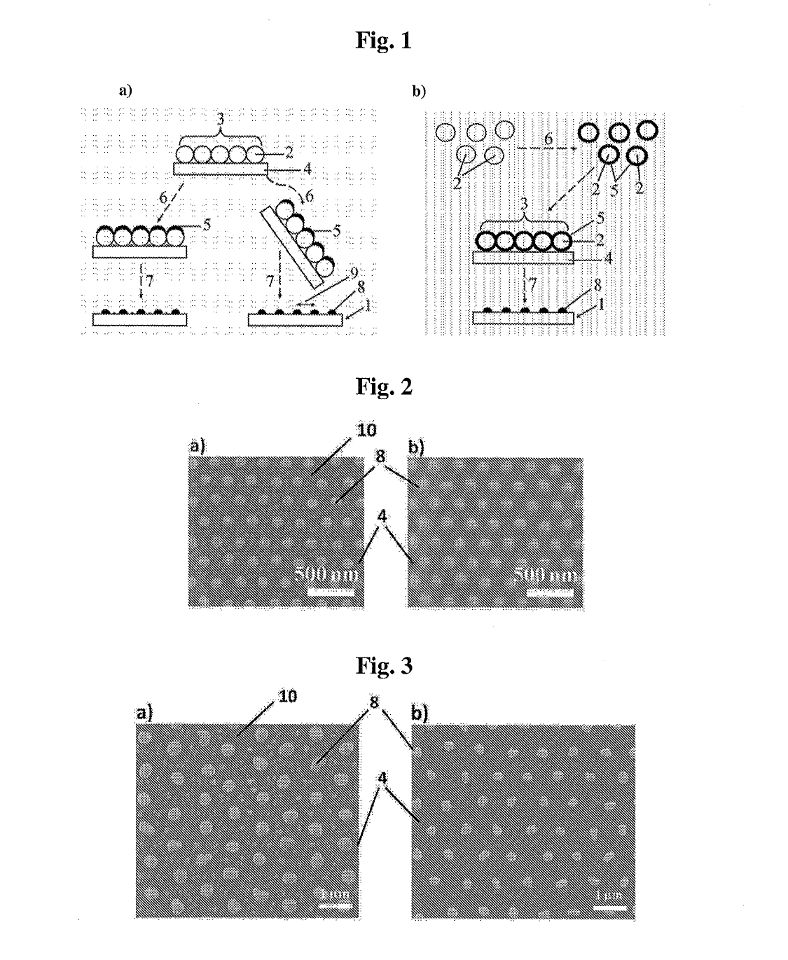

FIG. 1 a) is a schematic diagram of a production method for metal-nanoparticle arrays, b) is a schematic diagram of a production method for metal-nanoparticle arrays,

FIG. 2 a) shows a scanning-electron-microscope (SEM) image of a typical metal-nanoparticle array with undesirable metal-nanoparticle substructures, b) shows a SEM image of a typical metal-nanoparticle array,

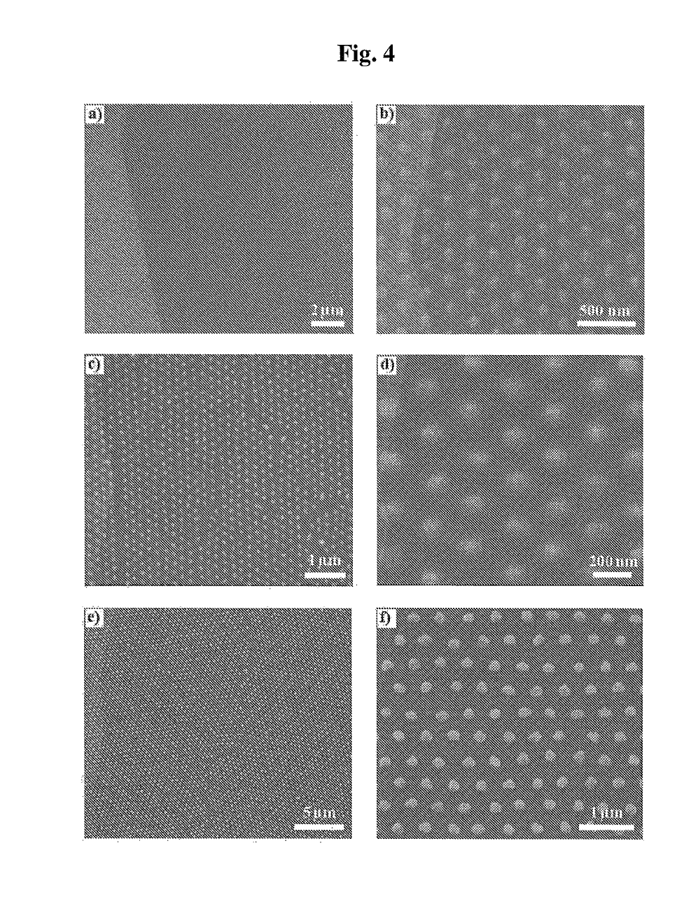

FIG. 3 a) shows a SEM image of a typical Au-nanoparticle array with undesirable metal-nanoparticle substructures, which has silicon as substrate, b) shows a SEM image of a typical Au-nanoparticle array following wet-chemical etching,

FIG. 4 a-f show examples of metal-nanoparticle arrays produced by flame-annealing,

FIG. 5 a-b show metal-nanoparticle arrays with different interparticle distances and various metal-layer thicknesses,

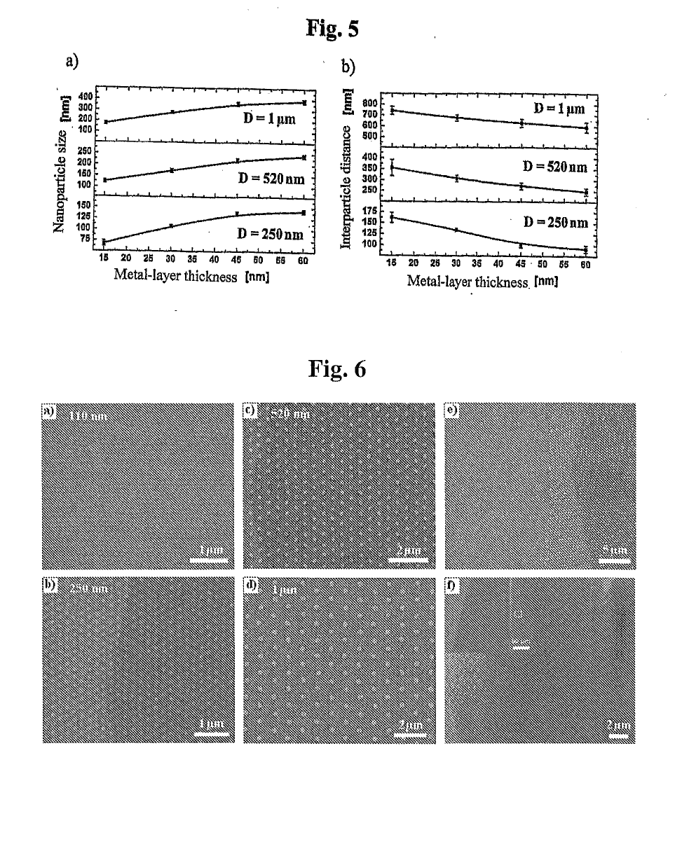

FIG. 6 a-f show examples of gold nanoparticles with different nanoparticle diameters as metal-nanoparticle arrays for which silicon was used as substrate,

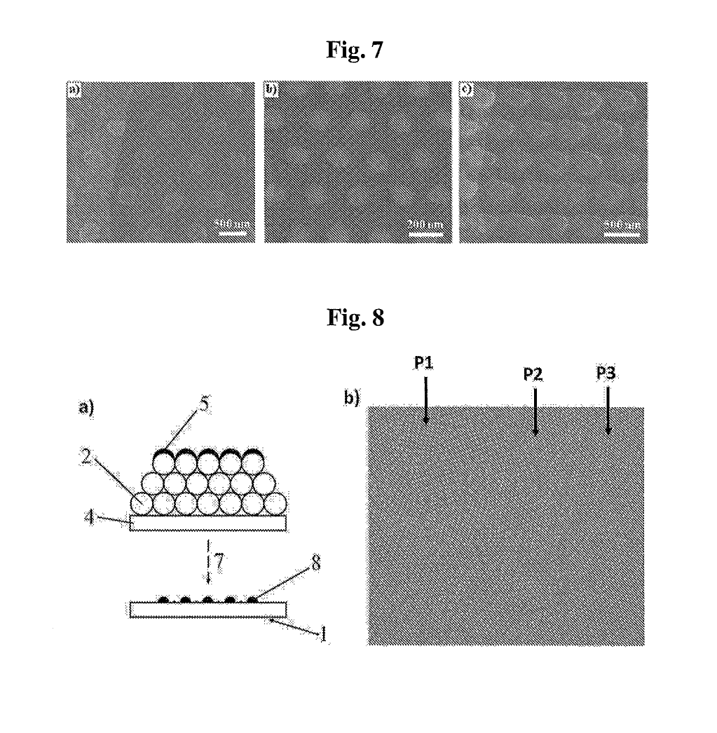

FIG. 7 a-c show examples of metal-nanoparticle arrays for which different substrates were used,

FIG. 8 a) is a schematic diagram of metal-coated polymeric multilayers and b) is a SEM image of a typical multilayer array.

FIG. 1a) is a schematic diagram of a production method according to the invention for metal-nanoparticle arrays (1). In a first step, a colloidal dispersion of microspheres (2) is deposited on a substrate (4) as a densely packed monolayer (3) via collective assembly. Thereafter, the deposited monolayer (3) is coated with at least one thinly deposited metal-nanoparticle layer (5) by means of a physical deposition process (6). The physical deposition process (6) may be conducted at perpendicular incidence (0°, see the left variant) or at oblique incidence (preferably at an angle of between 45°-70°, but not limited thereto, see the right variant in FIG. 1a)). The metal-nanoparticle layer (5) may already be present as a layer prior to the coating step. However, it is also conceivable for the metal-nanoparticles (8) to be present as a fine powder, a dispersion or another form and to be applied in such a way that a metal-nanoparticle layer (5) is formed on the deposited monolayer (3). Following coating, the microspheres (2) deposited on the substrate (4) as a monolayer (3) and coated with at least one metal-nanoparticle layer (5) are removed by thermal decomposition (7).

In a further method according to the invention (diagram in FIG. 1b), the microspheres (2) are first coated with at least one thinly deposited metal-nanoparticle layer (5) via a physical deposition method (6). Thereafter, the microspheres (2) coated with at least one metal-nanoparticle layer (5) are dispersed colloidally, after which the colloidal dispersion of microspheres (2) coated with a metal-nanoparticle layer (5) is deposited on a substrate (4) as a densely packed monolayer (3) via convective assembly. Following this step, the microspheres (2) coated with at least one metal-nanoparticle layer (5) and deposited on the substrate (4) as a monolayer (3) are removed by thermal decomposition (7).

As shown diagrammatically in FIGS. 1a) and 1b), metal-nanoparticle arrays (1) consisting of metal nanoparticles (8) on a substrate (4) are produced by way of this method. The metal nanoparticles (8) are applied indirectly to the substrate (4) via physical deposition (6) onto a monolayer (3) of densely packed microspheres (2). The processes of joining (annealing) of the metal nanoparticles (8) to the substrate (4) and thermal decomposition (7) of the monolayer (3) of densely packed microspheres (2) are simultaneous, the microspheres (2) then being removed, the at least one metal-nanoparticle layer (5) being sintered with the substrate, the metal nanoparticles (8) having a diameter of between 100 nm and 1 μm and the metal nanoparticles (8) having an interparticle distance (9) of between 50 nm and 1.5 μm.

As is shown in FIGS. 2a to 2b, the incidence at which the coating is physically deposited (6) on the monolayer (3) determines whether undesirable metal-nanoparticle substructures (10) and metal nanoparticles (8) or only the desired metal nanoparticles (8) are sintered with, or on, a substrate (4) following thermal decomposition (7) of the microspheres (2), where thermal decomposition (7) may be conducted in a furnace or by using an ethanol flame. If the physical deposition process (6) is conducted at perpendicular incidence (0°, see FIG. 2a), metal nanoparticles (8) and metal-nanoparticle substructures (10) form, which are sintered with, or on, a substrate (4). If, however, the physical deposition process (6) is conducted at oblique incidence (preferably at an angle of between 45°-70°, see FIG. 2b), only metal nanoparticles (8) are formed, which are sintered with, or on, a substrate (4). According to the invention, therefore, the physical deposition process (6) is advantageously conducted at oblique incidence (preferably at an angle of between 45°-70°).

FIG. 3a) shows a scanning-electron-microscope (SEM) image of a typical metal-nanoparticle array (1) comprising metal nanoparticles (8) and undesirable metal-nanoparticle substructures (10). The substrate (4) for the metal-nanoparticle array (1) consists in this example of silicon. The metal was applied onto the microspheres (2) by a physical deposition process (6) (in this case sputtering at perpendicular incidence), after which it was sintered with the substrate (4) at 650° C. for an hour via thermal decomposition (7) of the microspheres (2). Thermal decomposition (7) may be conducted in a furnace or by using an ethanol flame. The metal selected for the metal-nanoparticle layer (5) or the metal nanoparticles (8) was gold (Au). The metal nanoparticles (8) and the metal-nanoparticle substructures (10) are sintered with, or on, a substrate (4).

As the metal-nanoparticle substructures (10) are not desired, these may be removed following thermal decomposition (7), for example by way of wet-chemical etching, where aqueous I2/KI:H₂O (1:10) is used as etching solution. FIG. 3b) shows a metal-nanoparticle array (1) with gold as metal and silicon as substrate (4) after the wet-chemical etching step, and therefore without the undesirable metal-nanoparticle substructures (10).

Thermal decomposition (7) of the microspheres (2) and sintering (joining or also annealing) is possible both in a furnace and by using an ethanol flame, the latter being substantially faster (<2 min) irrespective of which side of the metal-nanoparticle array (1) to be sintered is held in the ethanol flame. FIGS. 4a) to 4f) show examples of metal-nanoparticle arrays (1) produced by using an ethanol flame for 2 minutes. FIGS. 4a) and 4b) show metal-nanoparticle arrays (1) where the metal selected for the metal-nanoparticle layer (5) or the metal nanoparticles (8) was gold (Au). The substrate (4) for the metal-nanoparticle arrays (1) shown in FIGS. 4a) and 4b) consisted of quartz glass. FIGS. 4c) and 4d) show metal-nanoparticle arrays (1) where the metal selected for the metal-nanoparticle layer (5) or the metal nanoparticles (8) was platinum (Pt). The substrate (4) for the metal-nanoparticle arrays (1) again consisted of quartz glass. In FIGS. 4a) to 4d), the ethanol flame was directed at the front side of the metal-nanoparticle array (1). FIGS. 4e) and 4f) show metal-nanoparticle arrays (1) where the metal selected for the metal-nanoparticle layer (5) or the metal nanoparticles (8) was platinum (Pt). However, the substrate (4) for the metal-nanoparticle arrays (1) was in this case silicon. In FIGS. 4e) to 4f), the ethanol flame was directed at the back of the metal-nanoparticle array (1).

The size of the metal nanoparticles (8) and the interparticle distances (9) may be adjusted via the thickness of the metal-nanoparticle layer (5) and the diameter (D) of the microspheres (2). The volume of the metal-nanoparticle layer (5) on each individual microsphere (2) correlates here with the size of the sintered metal nanoparticle (8). The influence of the diameter (D) of the microspheres (2) and the influence of the thickness of the metal-nanoparticle layer (5) on the size of the metal nanoparticles (8) and the interparticle distances (9) between the metal nanoparticles (8) is shown in FIGS. 5 a) to b).

Metal-nanoparticle arrays (1) with a narrow size distribution can be obtained by using microspheres (2) with diameters (D) of between 110 nm and 1 μm. FIGS. 6 a) to d) show SEM images of metal-particle arrays (1) on silicon as substrate (4) of monolayers (3) of microspheres (2) with various diameters (D). The diameter (D) of the microspheres (2) is 110 nm in FIG. 6a), 250 nm in FIG. 6b), 520 nm in FIGS. 6c) and 1 μm in FIG. 6d. The monolayer (3) was sputtered with gold (Au) at 45° incidence and then sintered at 700° C. for 1 h. FIG. 6e) shows the difference between stochastic particles generated by de-wetting of the initial metal layer that was deposited on the bare substrate (FIG. 6e, left) and ordered particles produced following thermal decomposition (7) of the metal-coated microsphere monolayer (FIG. 6e, right). The approach proposed here is not limited to flat substrates (4): 3-D objects may also be textured. An example of this is shown in FIG. 6f). A glass tube (diameter=180 μm) was provided with a metal(gold)-nanoparticle (8) pattern following decomposition (7) of the microsphere monolayer applied by dip coating. The microspheres (2) have a diameter (D) of 520 nm. The insert in FIG. 6f) is a magnification of the selected area on the tube surface.

It is furthermore possible to produce metal-nanoparticle arrays (1) on other substrates (4) or substrate types, such as quartz glass (FIG. 7a)), sapphire (FIG. 7b)) or polyimide (FIG. 7c)). The SEM images shown in FIGS. 7 a) to c) are Exemplary of these Substrates. The Sintering temperature depends both on the metal to be used and on the type of substrate. Temperatures in the range from 500-700° C. were used for silicon, sapphire and quartz substrates. Although the methods work particularly well at these (highish) temperatures, they may also be used for substrates with a limited thermal budget. For example, substrates (4) of polyimide may be sintered at 380° C., which is below the glass transition temperature of polyimide. Glass, mica, metal, ceramic or oxidic materials can also be used as substrates (4).

FIG. 8a)-b) show that the methods of producing metal-nanoparticle arrays (1) are not only applicable to monolayers (3) of microspheres (2). The top part of FIG. 8a) is a diagram of a multilayer (here comprising three layers); the topmost monolayer (3) of microspheres (2) is coated with a layer of metal nanoparticles (5). Following thermal decomposition (7) of the microspheres (2) and sintering (joining or annealing), a metal-nanoparticle array (1) is likewise obtained. This metal-nanoparticle array (1) is shown as a SEM image in FIG. 8b). Arrow 1 (P1) shows metal nanoparticles (8) of the third layer, arrow 2 (P2) metal nanoparticles (8) of the second layer and arrow 3 (P3) metal nanoparticles (8) of the first layer.

1. Method of producing metal-nanoparticle arrays (1), wherein
a colloidal dispersion of microspheres (2) is deposited on a substrate (4) as a densely packed monolayer (3) via convective assembly,
after which the deposited monolayer (3) is coated with at least one thinly deposited metal-nanoparticle layer (5) by means of a physical deposition process (6), and
after which the microspheres (2) deposited on the substrate (4) as a monolayer (3) and coated with at least one metal-nanoparticle layer (5) are removed by thermal decomposition (7).

2. Method of producing metal-nanoparticle arrays (1), wherein
microspheres (2) are coated with at least one thinly deposited metal-nanoparticle layer (5) by means of a physical deposition process (6),
after which the microspheres (2) coated with at least one metal-nanoparticle layer (5) are dispersed colloidally,
after which the colloidal dispersion of microspheres (2) coated with a metal-nanoparticle layer (5) is deposited on a substrate (4) as a densely packed monolayer (3) by convective assembly, and
after which the microspheres (2) coated with at least one metal-nanoparticle layer (5) and deposited on the substrate (4) as a monolayer (3) are removed by thermal decomposition (7).

3. Metal-nanoparticle array (1) comprising metal nanoparticles (8) applied on a substrate (4), wherein the metal nanoparticles (8) are applied indirectly to the substrate (4) via physical deposition (6) onto a monolayer (3) of densely packed microspheres (2), the metal nanoparticles (8) bonding to the substrate (4) as a result of thermal decomposition (7) of the monolayer (3) of densely packed microspheres (2), to the effect that;
the microspheres (2) are removed,
the at least one metal-nanoparticle layer (5) is sintered with the substrate,
the metal nanoparticles (8) have a diameter of between 100 nm and 1 μm and
an interparticle distance (9) of between 50 nm and 1.5 μm.

4. Metal-nanoparticle array (1) according to claim 3, wherein the metal-nanoparticle layer has a thickness of between 10 nm and 1 μm.

5. Metal-nanoparticle array (1) according to claim 3, wherein the metal nanoparticles (8) have a diameter of at least 260 nm.

6. Metal-nanoparticle array (1) according to claim 3, wherein the metal nanoparticles (8) have an interparticle distance (9) of at least 500 nm.

7. Metal-nanoparticle array (1) according to claim 3, wherein the metal nanoparticles (8) are arranged in hexagonal arrays.

8. Method according to claim 1, wherein the microspheres (2) have a diameter of between 90 nm and 1.2 μm.

9. Method according to claim 1, wherein the substrate (4) comprises silicon, silicon, glass, quartz glass, a monocrystal, sapphire, polyimide, polytetrafluoroethylene (PTFE) or other oxidic materials, ceramics or metal.

10. Method according to claim 1, wherein the substrate (4) has a 2-D surface or a 3-D surface.

11. Method according to claim 1, wherein the physical deposition method (6) is sputtering, electron beam evaporation, thermal evaporation or pulsed laser deposition.

12. Method according to claim 1, wherein the metal of the metal-nanoparticle layer (5) or of the metal nanoparticles (8) is a precious metal.

13. Method according to claim 12, wherein the precious metal is gold (Au), silver (Ag) or platinum (Pt).

14. Method according to claim 1, wherein thermal decomposition (7) is conducted in a furnace or by using an ethanol flame.

15. Method according to claim 1, wherein between 90 and 100% of the metal nanoparticles (8) used initially are incorporated in the metal-nanoparticle array (1).

16. Method according to claim 1, wherein metal-nanoparticle substructures (10) formed during production are removed following thermal decomposition (7) by means of wet-chemical etching, aqueous I₂/KI being used as etching solution.

17. Method according to claim 1, wherein the metal nanoparticles (8) are sintered with the substrate (4) at a temperature of between 350° C. and 400° C. or between 500° C. and 700° C.
